(19) United States
(12) Patent Application Publication
(10) Pub. No.: US 2012/0075793 A1
(43) Pub. Date: Mar. 29, 2012

(54) CONNECTION STRUCTURE HAVING GUIDING MECHANISM

(75) Inventors: Chih-Hsiang CHIEN, Taipei (TW); An-Sheng Weng, Taipei (TW); His-Yun Chen, Taipei (TW); Hsin-Hung Lai, Taipei (TW); Chun-Te Lee, Taipei (TW); Cheng-Min Chang, Taipei (TW); Chai-Wei Shih, Taipei (TW)

(73) Assignee: SHUTTLE INC.

(21) Appl. No.: 12/890,679

(22) Filed: Sep. 26, 2010

(51) Int. Cl. H05K 7/00

(52) U.S. Cl. 361/679.41

(57) ABSTRACT

A connection structure having guiding mechanism includes a female connector, a sensing unit and a status-indicating unit arranged on an electronic device, and a male connector, a trigger element and a status-indicating unit arranged a docking station. While the electronic device is close to the docking station, the sensing unit will sense the trigger element and activate the status-indicating unit. Once the status-indicating unit is aligned to the position-marking unit by a user, the female connector will be aligned to the male connector.

### BACKGROUND OF THE INVENTION

1. Field of the Invention

The present invention relates to a connection structure, particularly relates to a connection structure having a guiding mechanism for user to perform connection processing rapidly and accurately.

2. Description of Related Art

The development of the semiconductor industry promotes the development of portable electronic products in recent years. Such portable electronic products like mobile phones, MP4 players, personal digital assistants (PDAs), and tablet PCs (such as Apple's iPad) are widely used in people's lives.

The portable electronic devices not only can be carried by users, but also can be connected with computers as needed to be remotely controlled by the computers for sorting and updating data information. Besides, the most of the portable electronic devices having rechargeable batteries can be recharged by the power suppliers of the computers.

FIG. 1 shows a schematic view illustrating the conventional electronic device. The electronic device 11 can be directly connected to a computer 13 by a transmission line. Alternatively, the electronic device 11 can also be connected to the computer 13 through a docking station 12. As illustrated in FIG. 1, the electronic device 11 has a female connector 110 for connecting to a male connector 120 of the docking station 12 which is connected with the computer 13. Besides, the docking station 12 can physically support the electronic device 11 and provide a comfortable viewing angle of the screen 111 of the electronic device 11 for a user. Thus, the user can operate both the electronic device 11 and the computer 13 in the same time and deal with some communication issues between them.

However, conventional electronic devices 11 and docking stations 12 do not have any guiding mechanism for helping them connect with each other. Users have to adjust the position of the electronic device 11 in order to carefully connect the female connector 110 with the male connector 120 of the docking station 12.

In addition, the female connector 110 is often located at the bottom side of the electronic device 11 where is not easy to view to the user when performing the mentioned connection. The user has to stay close to the bottom side of the electronic device 11 to see the female connector 110, so as to accurately connect the female connector 110 to the male connector 120. Such an inconvenience can be worse in some cases where the connector 110 and 120 are located at the middle positions of the electronic device 11 and the docking station 12, respectively.

Therefore, there is a need that a connection structure having a guiding mechanism should be provided on the electronic device 11 and the docking station 12, and thus helps their connection become rapidly and accurately.

### SUMMARY OF THE INVENTION

The object of the present invention is to provide a connection structure having guiding mechanism, which provides the guiding mechanism for users to perform the connection between the electronic device and the docking station rapidly and accurately.

For achieving the object, the present invention provides a connection structure having guiding mechanism including a female connector, a sensing unit and a status-indicating unit arranged on an electronic device, and a male connector, a trigger element and a status-indicating unit arranged a docking station. While the electronic device is close to the docking station, the sensing unit will sense the trigger element and activate the status-indicating unit. Once the status-indicating unit is aligned to the position-marking unit by a user, the female connector will be aligned to the male connector.

Compared to the conventional art, the present invention has the advantages that once the status-indicating unit is aligned to the position-marking unit by a user, the female connector on the electronic device will be rapidly and accurately aligned to the male connector on the docking station. The user no longer has to stay close to the bottom side of the electronic device to see the female connector while performing the connection. Besides, the status-indicating unit emits light beam for alignment, which enables the possibility of performing the connection in a dark environment.

### BRIEF DESCRIPTION OF THE DRAWINGS

FIG. 1 shows a schematic view illustrating the conventional electronic device;

FIG. 2A is a schematic view illustrating an electronic device according to an embodiment of the invention;

FIG. 2B is a schematic view illustrating a docking station according to an embodiment of the invention;

FIG. 3A is a schematic view illustrating a step according to an embodiment of the present invention;

FIG. 3B is a schematic view illustrating another step according to an embodiment of the present invention;

FIG. 3C is a schematic view illustrating another step according to an embodiment of the present invention;

FIG. 4A shows a schematic view illustrating the position-marking unit according to a first embodiment of the present invention;

FIG. 4B shows a schematic view illustrating the position-marking unit according to the second embodiment of the present invention;

FIG. 4C is a schematic view of the position-making unit according a third embodiment of the present invention;

FIG. 4D is a sectional view of the position-making unit according a third embodiment of the present invention;

FIG. 5A is a schematic views according to another embodiment of the present invention;

FIG. 5B is another schematic views according to another embodiment of the present invention;

FIG. 6A shows the position-marking unit according to the fourth embodiment of the present invention;

FIG. 6B shows the position-marking unit according to the fifth embodiment of the present invention;

FIG. 6C shows the position-marking unit according to the sixth embodiment of the present invention;

FIG. 6D is a sectional view of the position-marking unit according to the sixth embodiment of the present invention;

FIG. 7A is a schematic view of the connection structure according to another embodiment of the present invention;

FIG. 7B is another schematic view of the connection structure according to another embodiment of the present invention; and

FIG. 7C is a schematic view of the connection structure according to another embodiment of the present invention.

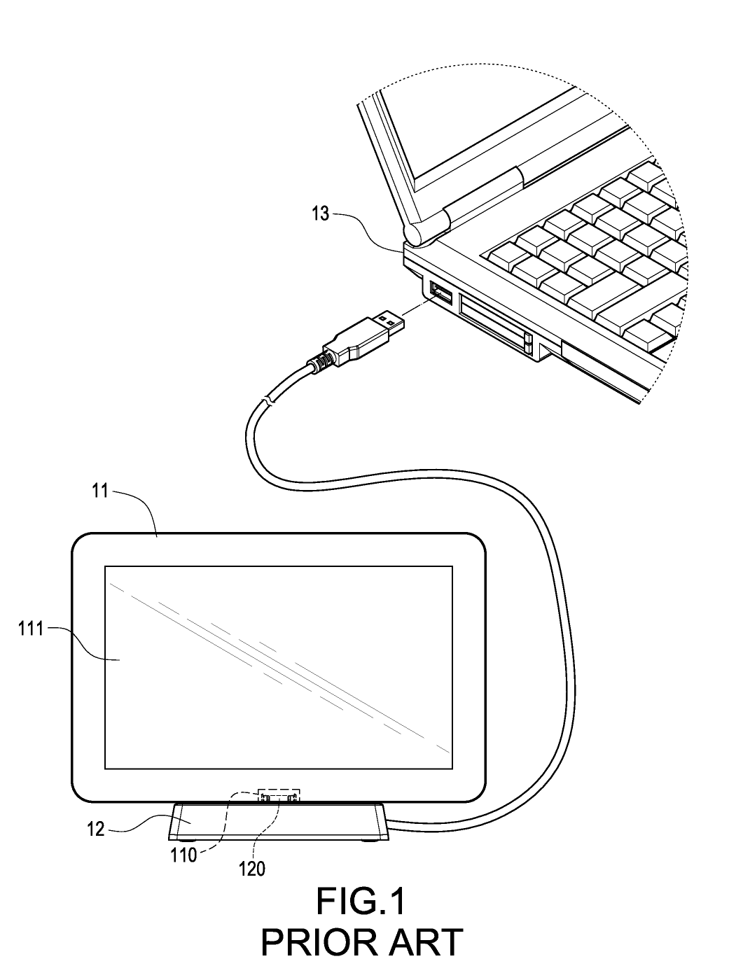

### DETAILED DESCRIPTION OF THE INVENTION

The present invention is described below in detailed with the reference to accompanying drawings. It should be mentioned that the drawings are provided for illustration only and the invention is not limited to the drawings.

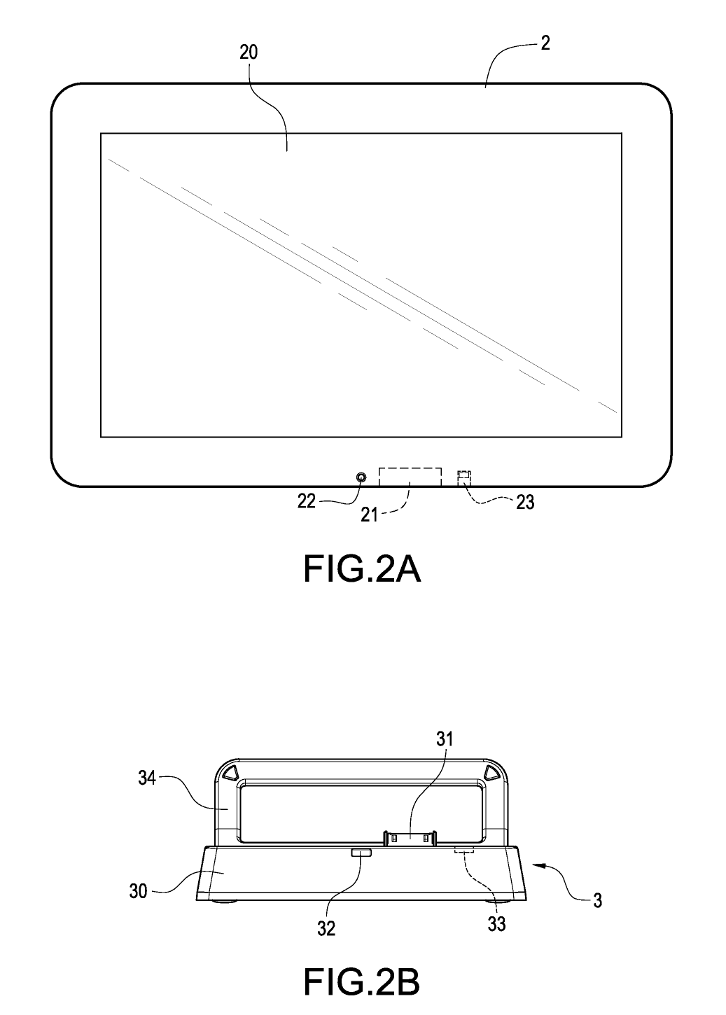

FIG. 2A and FIG. 2B are the schematic views illustrating an electronic device 2 and a docking station 3, respectively, according to an embodiment of the present invention. The connection structure includes a female connector 21, a sensing unit 22 and a status-indicating unit 23 all arranged on the electronic device 2. The connection structure also includes a male connector 31, a position-marking unit 32 and a trigger element 33 all arranged on the docking station 3. It should be mentioned that the numbers and the positions of the sensing unit 22, the status-indicating unit 23, the position-marking unit 32 and the trigger element 33 may have several kinds of variations. In another aspect, for design technical reasons, the female connector 21 and the male connector 31 may not be located at the centers of the electronic device 2 and the docking station 3, respectively. It is more difficult to perform their connection without the connection structure of the present invention.

The electronic device 2 also includes a screen 20 for displaying information images generated by the inner system of the electronic device 2. As FIG. 2A shows, the female connector 21 is embedded in a bottom side of the electronic device 2. The status-indicating unit 22 and the sensing unit 23 are arranged adjacent to the female connector 21. The sensing unit 23 is electrically connected to the status-indicating unit 22. As FIG. 2B shows, the docking station 3 includes a base 30. The male connector 31 is arranged on the base 30. The position-marking unit 32 and the trigger element 33 are arranged inside the base 30. A back plate 34 is arranged on the top side of the base 30 for supporting the electronic device 2 in a standing position when the electronic device 2 is connected to the docking station 3.

In this embodiment, the status-indicating unit 22 can be a light-emitting diode (LED). The sensing unit 23 can be a magnetic sensor such as a Hall sensor. The trigger element 33 can be a magnet or the like, but not limited thereto.

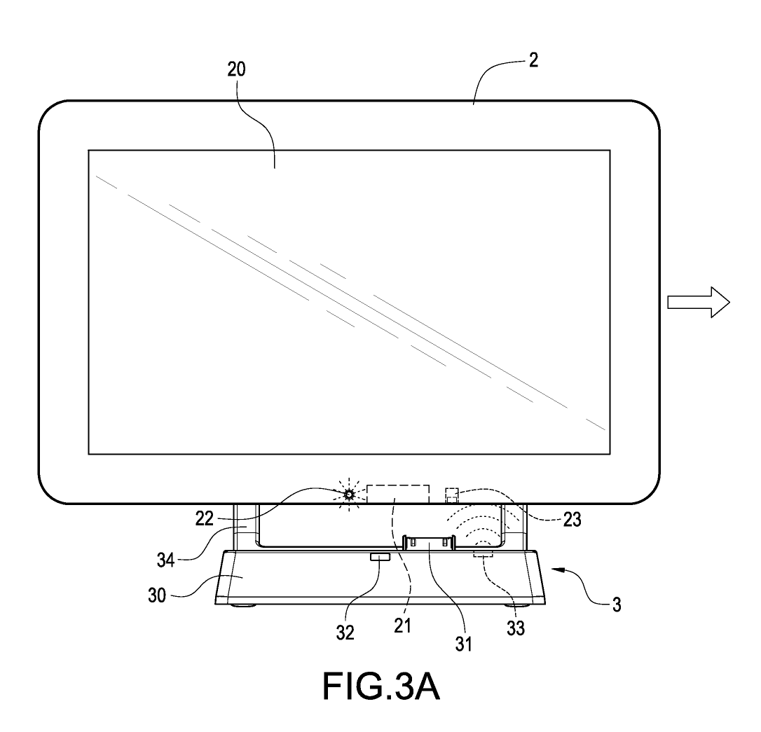

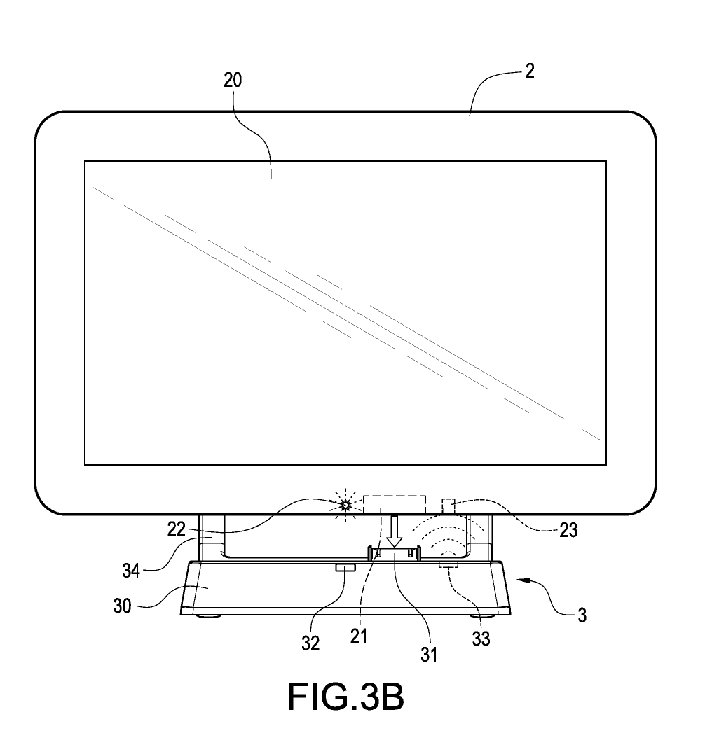

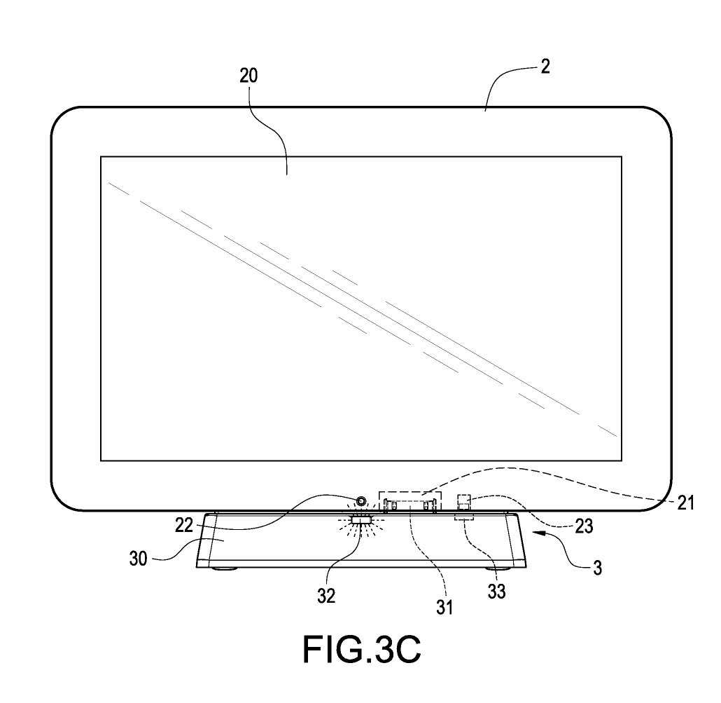

FIG. 3A, FIG. 3B and FIG. 3C are schematic views illustrating consecutive steps according to an embodiment of the present invention. In FIG. 3A, the trigger element 33 has a magnetic field by which the sensing unit 23 senses the presence of the trigger element 33 while the electronic device 2 is close to the docking station 3. The sensing unit 23 will activate the status-indicating unit 22. If the status-indicating unit 22 is a LED, it will emit light by then.

As FIG. 3B shows, the distance between the status-indicating unit 22 and the female connector 21 is equal to the distance between the position-marking unit 32 and the male connector 31. It enables that the female connector 21 will be simultaneously aligned to the male connector 31; once the activated status-indicating unit 22 is aligned to the position-marking unit 32 by a user. Then, as FIG. 3C shows, the electronic device 2 can be moved downwardly to connect to the docking station 3. It should be mentioned that no matter whether the status-indicating unit 22 emits light or not, user can indentify the status-indicating unit 22 and align it to the position-marking unit 32. But in a dark environment, the light emitted by the status-indicating unit 22 can help such an alignment rapidly and accurately.

There are several alternative variations of the position-marking unit 32. As FIG. 3C shows, the position-marking unit 32 can be a LED which is electrically connected to the male connector 31. After the status-indicating unit 22 is aligned to the position-marking unit 32 and the electronic device 2 is connected to the docking station 3, the status-indicating unit 22 will put off and the position-marking unit 32 will light up, so as to inform the finish of the connection.

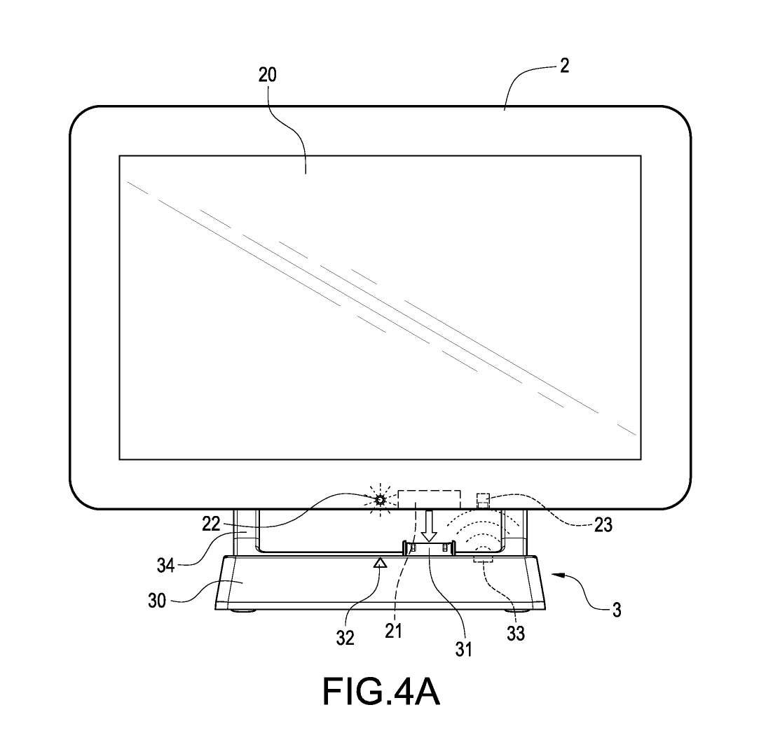

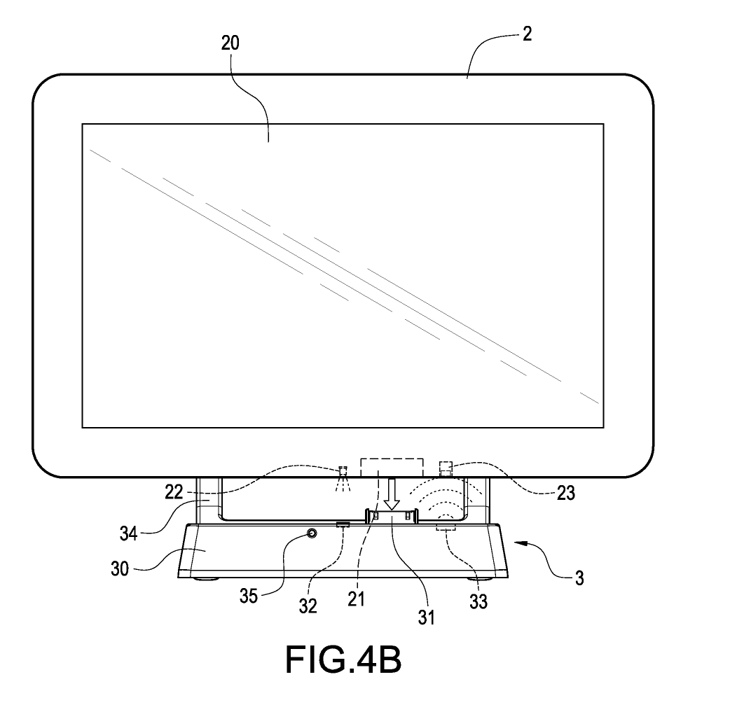

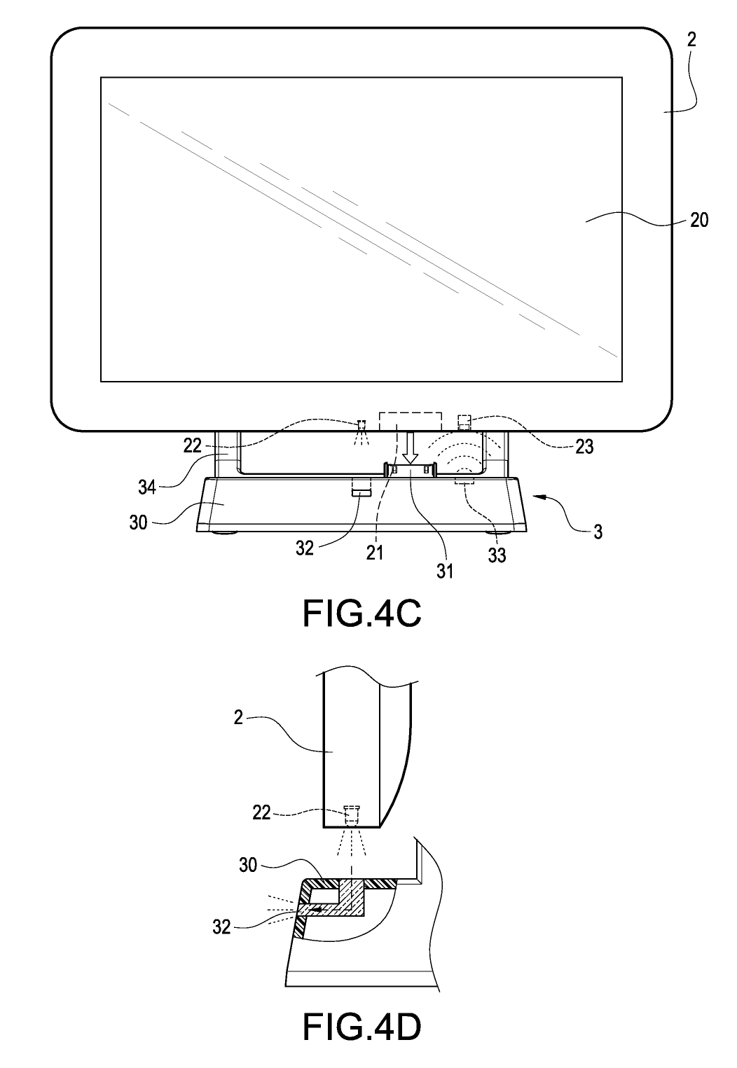

Moreover, FIG. 4A shows a schematic view illustrating the position-marking unit 32. The position-marking unit 32 can be a sign or a pattern, such as a triangle pattern as shown or even a trademark of the maker of the docking station 3. In this embodiment, the position-marking unit 32 is simply a mark for user to align with the status-indicating unit 22 in a bright environment.

FIG. 4B shows a schematic view illustrating the position-marking unit according to the second embodiment of the present invention. In this embodiment, the position-marking unit 32 can be a light-sensing strip arranged on the top side of the docking station 3. The docking station 3 further includes a connection-indicating unit 35 electrically connected to the male connector 31. The connection-indicating unit 35 can be a light-emitting diode. In this embodiment, the status-indicating unit 22 is a light-emitting diode or a laser source exposed out of the bottom side of the electronic device 2. Once the status-indicating unit 22 is activated to emit a light beam downwardly from the bottom side of the electronic device 2, and the electronic device 2 is move to a position where the status-indicating unit 22 is aligned to the position-marking unit 32, the position-marking unit 32 will receive and gather the light beam to inform the finish of the alignment between the female connector 21 and the male connector 31. Then, once the female connector 21 is connected to the male connector 31, the connection-indicating unit 35 will be activated and the status-indicating unit 22 will be turned off to inform the finish of the connection of the female connector 21 and the male connector 31.

FIG. 4C and FIG. 4D are respectively a schematic view and a sectional view of the position-making unit 32 according a third embodiment of the present invention. In this embodiment, the position-marking unit 32 can be an L-shaped transparent tube arranged in the docking station 3 and exposed out of a top side and a front side of the docking station 3 as shown in FIG. 4D. The L-shaped transparent tube, for example, can be made of acrylic material. The status-indicating unit 22 is a light-emitting diode or a laser source exposed out of the bottom side of the electronic device 2. Once the sensing unit 23 senses the trigger element 33, the status-indicating unit 22 is activated by the sensing unit 23 to emit a light beam downwardly from the bottom side of the electronic device 2, and then the electronic device 2 is move to a position where the status-indicating unit 22 is aligned to the position-marking unit 32, the position-marking unit 32 will receive the light beam through the top side of the docking station 3, and the light beam will be deflected through an inner channel to the front side of the docking station 3 to inform the finish of the alignment between the female connector 21 and the male connector 31.

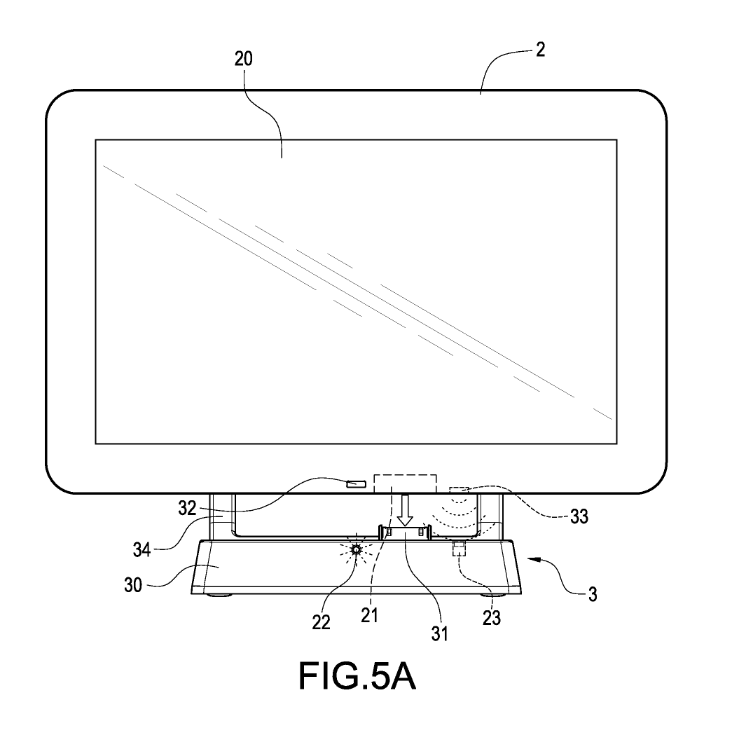

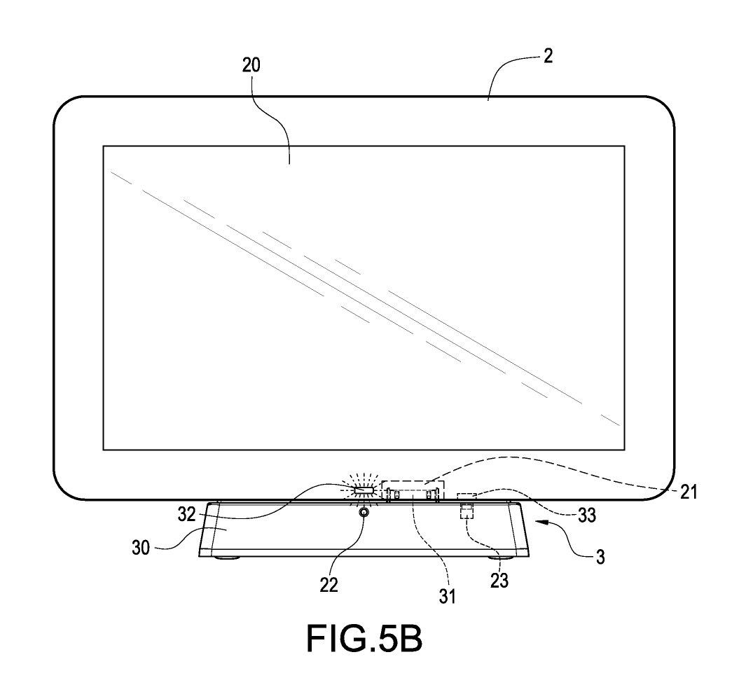

FIG. 5A and FIG. 5B are schematic views according to another embodiment of the present invention. In alternative configurations, the positions of the status-indicating unit 22, the sensing unit 23, the position-marking unit 32 and the trigger element 33 can be switched, with the status-indicating unit 22 and the sensing unit 23 being arranged on the docking station 3, and the position-marking unit 32 and the trigger element 33 arranged on the electronic device 2. Similarly, in order to align the female connector 21 to the male connector 31 by aligning the status-indicating unit 22 with the position-marking unit 32, the distance between the position-marking unit 32 and the female connector 21 should be made equal to the distance between the status-indicating unit 22 and the male connector 31.

As FIG. 5A shows, while the electronic device 2 is close to the docking station 3, and the trigger element 33 is sensed by the sensing unit 23, the sensing unit 23 will activate the status-indicating unit 22. Once the position-marking unit 32 is aligned to the status-indicating unit 22, the female connector 21 will be aligned to the male connector 31 at the same time. Then, as FIG. 5B shows, user can downwardly move the electronic device 2 to connect it to the docking station 3. Assuming the position-marking unit 32 is a light-emitting diode as shown in FIG. 3C, after the electronic device 2 is connected to the docking station 3, the status-indicating unit 22 will be turned off and the position-marking unit 32 will light on to inform the finish of the connection.

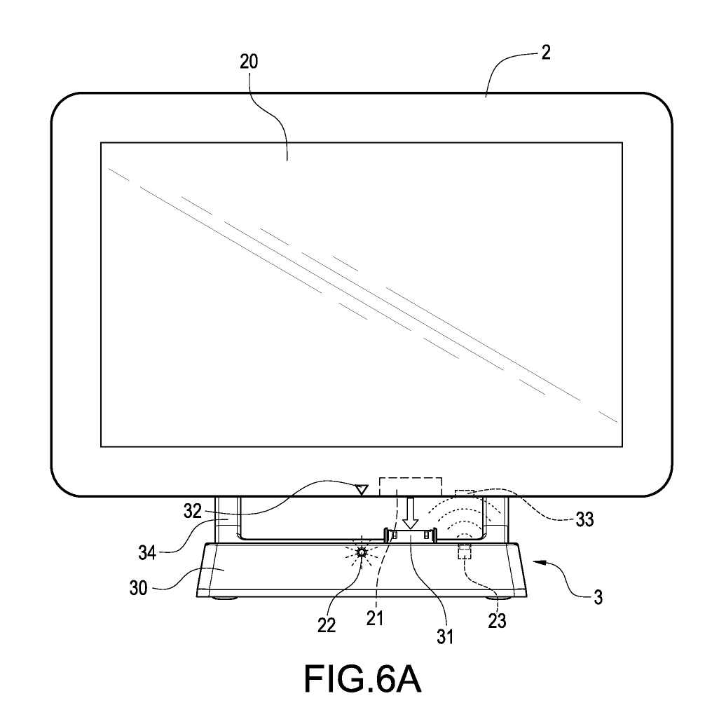

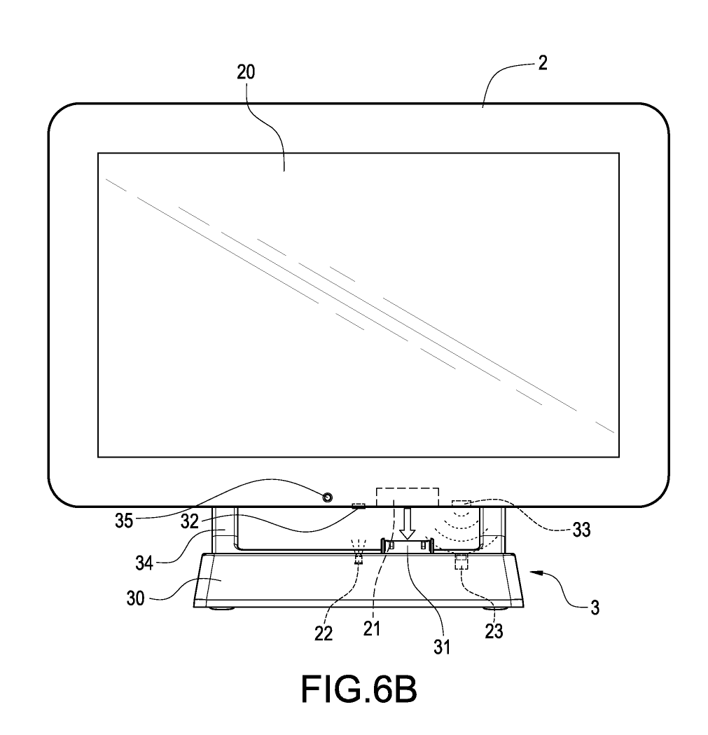

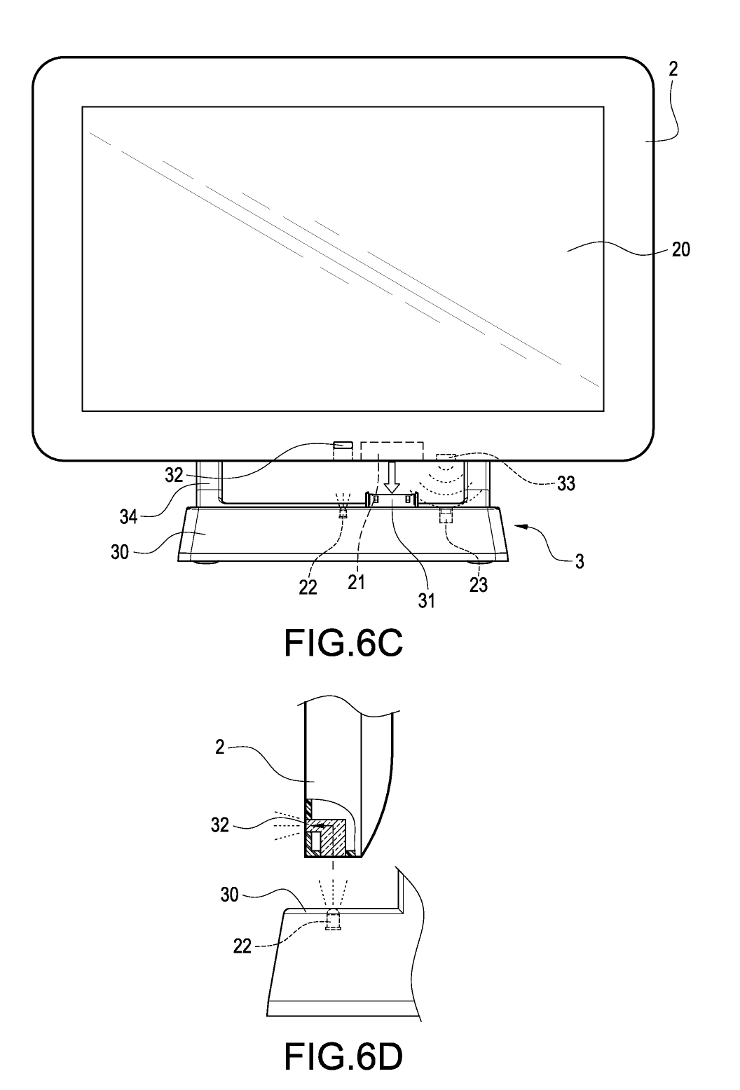

FIG. 6A shows the position-marking unit 32 according to the fourth embodiment of the present invention. In this embodiment, the position-marking unit 32 on the electronic device 2 is a sign or a pattern as shown in FIG. 4A, which can be aligned to the status-indicating unit 22 in a bright environment.

FIG. 6B shows the position-marking unit 32 according to the fifth embodiment of the present invention. In this embodiment, the position-marking unit 32 on the electronic device 2 is a light-sensing strip arranged on the bottom side of the electronic device 2 as shown in FIG. 4B, as well as the electronic device 2 includes a connection-indicating unit 35 electrically connected to the female connector 21. The position-marking unit 22 on the bottom side of the electronic device 2 can receive and gather the light beam from the status-indicating unit 22 on the docking station 3 so as to inform the finish of alignment. After the female connector 21 is connected to the male connector 31, the connection-indicating unit 35 will be activated and the status-indicating unit 22 will be turned off to inform the finish of connection.

FIG. 6C shows the position-marking unit 32 according to the sixth embodiment of the present invention. In this embodiment, the position-marking unit 32 is an L-shaped transparent tube as shown in FIG. 4C. As FIG. 6D shows, the L-shaped transparent tube is arranged in the electronic device 2 and exposed out of a bottom side and a front side of the electronic device 2. The position-marking unit 32 on the bottom side of the electronic device 2 can receive the light beam emitted from the status-indicating unit 22 on the docking station 3. Then the light beam can be deflected to the front side of the electronic device 2.

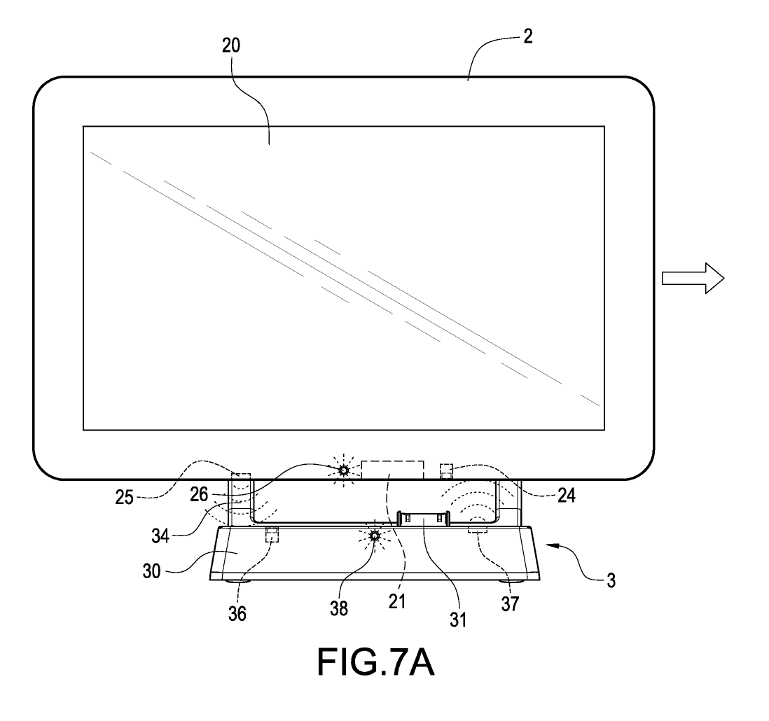

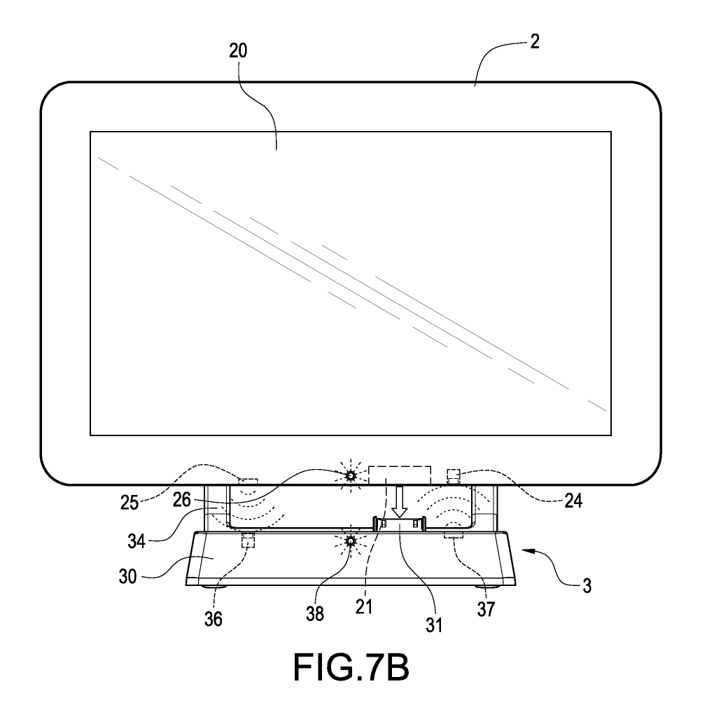

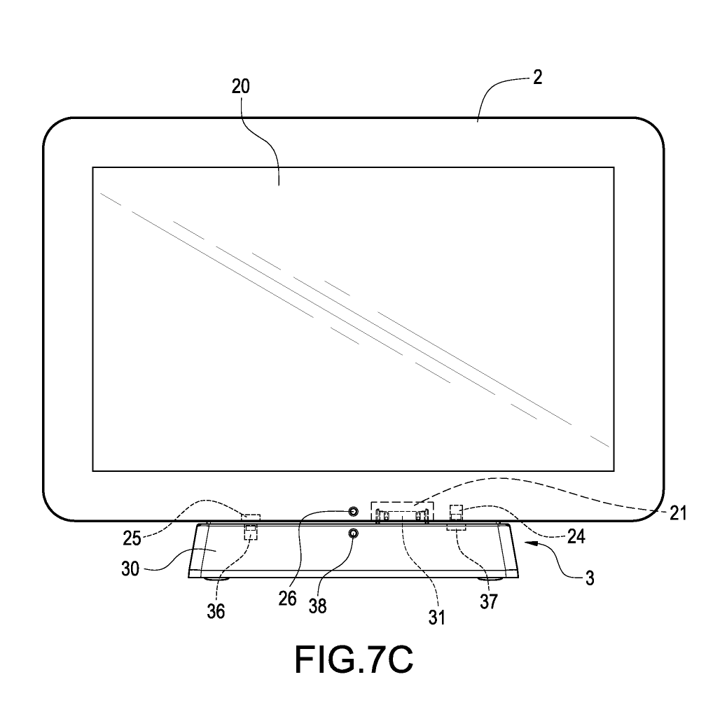

FIG. 7A, FIG. 7B and FIG. 7C are schematic views of the connection structure according to another embodiment of the present invention. The connection structure includes a female connector 21, a first sensing unit 24, a first trigger element 25 and a first position-indicating unit 26 all arranged at the same side of the electronic device 2. The first position-indicating unit 26 is electrically connected to the first sensing unit 24. The connection structure also includes a male connector 31, a second sensing unit 36, a second trigger element 37 and a second position-indicating unit 38 all arranged at the same side of the docking station 3. The second position-indicating unit 38 is electrically connected to the second sensing unit 36. The distance between the first position-indicating unit 26 and the female connector 21 is equal to the distance between the second position-indicating unit 38 and the male connector 31.

As FIG. 7A shows, while the electronic device 2 is close to the docking station 3, the first sensing unit 24 will sense the second trigger element 37 and then activate the first position-indicating unit 26, and the second sensing unit 36 will sense the first trigger element 25 and then activate the second position-indicating unit 38

As FIG. 7B shows, either the electronic device 2 or the docking station 3 can be moved by the user, and once the first position-indicating unit 26 is aligned to the second position-indicating unit 38, the female connector 21 will be aligned to the male connector 31. Then, as FIG. 7C shows, the user can move the electronic device 2 downwardly to connect it to the docking station 3. After the electronic device 2 is connected to the docking station 3, the first position-indicating unit 26 and the second position-indicating unit 38 will be turned off to inform the finish of the connection.

While the invention has been described by means of specific embodiments, numerous modifications and variations could be made thereto by those skilled in the art without departing from the scope and spirit of the invention set forth in the claims.

What is claimed is:

1. A connection structure having guiding mechanism arranged on an electronic device and a docking station, the connection structure comprising:
a female connector arranged on a side of the electronic device;
a male connector arranged on a side of the docking station;
a trigger element arranged in the docking station;
a sensing unit arranged in the electronic device for sensing the trigger element;
a status-indicating unit arranged on the electronic device and electrical connected to the sensing unit and capable of being activated by the sensing unit while the electronic device is close to the docking station and the sensing unit senses the trigger element;
a position-marking unit arranged on an outer surface of the docking station, wherein the distance between the status-indicating unit and the female connector is equal to the distance between the position-marking unit and the male connector, whereby an alignment between female connector and the male connector can be ensured when the activated status-indicating unit is aligned to the position-marking unit by moving the electronic device.

2. The connection structure as claim 1, wherein the status-indicating unit is a light-emitting diode and the sensing unit is a Hall sensor and the trigger element is a magnet.

3. The connection structure as claim 2, wherein the position-marking unit is a light-emitting diode electrically connected to the male connector, the position-marking unit is activated once the female connector is connected to the male connector.

4. The connection structure as claim 1, wherein the status-indicating unit is a light-emitting diode or a laser source exposed out of a bottom side of the electronic device, and the position-marking unit is a light-sensing strip arranged on a top side of the docking station, and the docking station further comprises a connection-indicating unit electrically connected to the male connector, and once the status-indicating unit is activated to emit a light beam downwardly from the bottom side of the electronic device and is aligned to the position-marking unit, the position-marking unit will receive and gather the light beam, and once the female connector is connected to the male connector, the connection-indicating unit will be activated.

5. The connection structure as claim 1, wherein the status-indicating unit is a light-emitting diode or a laser source exposed out of a bottom side of the electronic device, and the position-marking unit is an L-shaped transparent tube arranged in the docking station and exposed out of a top side and a front side of the docking station, and once the status-indicating unit is activated to emit a light beam downwardly from the bottom side of the electronic device and is aligned to the position-marking unit, the position-marking unit will receive the light beam through the top side of the docking station, and the light beam will be deflected to the front side of the docking station.

6. A connection structure having guiding mechanism arranged on an electronic device and a docking station, the connection structure comprising:
a female connector arranged on a side of the electronic device;
a male connector arranged on a side of the docking station;
a trigger element arranged in the electronic device;
a sensing unit arranged in the docking station for sensing the trigger element;
a status-indicating unit arranged on the docking station and electrical connected to the sensing unit and capable of being activated by the sensing unit while the electronic device is close to the docking station and the sensing unit senses the trigger element;
a position-marking unit arranged on an outer surface of the electronic device, wherein the distance between the position-marking unit and the female connector is equal to the distance between the status-indicating unit and the male connector, whereby an alignment between female connector and the male connector can be ensured when the activated status-indicating unit is aligned to the position-marking unit by moving the electronic device.

7. The connection structure as claim 6, wherein the status-indicating unit is a light-emitting diode and the sensing unit is a Hall sensor and the trigger element is a magnet.

8. The connection structure as claim 7, wherein the position-marking unit is a light-emitting diode electrically connected to the female connector, the position-marking unit is activated once the female connector is connected to the male connector.

9. The connection structure as claim 6, wherein the status-indicating unit is a light-emitting diode or a laser source exposed out of a top side of the docking station, and the position-marking unit is a light-sensing strip arranged on a bottom side of the electronic device, and the electronic device further comprises a connection-indicating unit electrically connected to the female connector, and once the status-indicating is activated to emit a light beam downwardly from the top side of the docking station and is aligned to the position-marking unit, the position-marking unit will receive and gather the light beam, and once the female connector is connected to the male connector, the connection-indicating unit will be activated.

10. The connection structure as claim 6, wherein the status-indicating unit is a light-emitting diode or a laser source exposed out of a top side of the docking station, and the position-marking unit is an L-shaped transparent tube arranged in the electronic device and exposed out of a bottom side and a front side of the electronic device, and once the status-indicating is activated to emit a light beam upwardly from the top side of the docking station and is aligned to the position-marking unit, the position-marking unit will receive the light beam through the bottom side of the electronic device, and the light beam will be deflected to the front side of the electronic device.

11. A connection structure having guiding mechanism for connecting an electronic device to a docking station, the electronic device comprising a female connector and the docking station comprising a male connector, wherein the improvement comprises:
a first sensing unit, a first trigger element and a first position-indicating unit all arranged on the electronic device and located at the same side of the female connector, wherein the first position-indicating unit is electrically connected to the first sensing unit; and
a second sensing unit, a second trigger element and a second position-indicating unit all arranged on the docking station and located at the same side of the male connector, wherein second position-indicating unit is electrically connected to the second sensing unit,
whereby while the electronic device is close to the docking station, the first sensing unit will sense the second trigger element and then activate the first position-indicating unit, and the second sensing unit will sense the first trigger element and then activate the second position-indicating unit, and the distance between the first position-indicating unit and the female connector is equal to the distance between the second position-indicating unit and the male connector,
whereby an alignment between the female connector and the male connector can be ensured when the first position-indicating unit is aligned to the second position-indicating unit.

12. The connection structure as claim 11, wherein the first position-indicating unit and the second position-indicating unit are light-emitting diodes, and first sensing unit and the second sensing unit are Hall sensors, and the first trigger element and the second trigger element are magnets.
